(19) United States
(12) Patent Application Publication
(10) Pub. No.: US 2007/0008774 A1
(43) Pub. Date: Jan. 11, 2007

(54) Phase change memory device and method of fabricating the same

(75) Inventor: Yoon-Ho Khang, Yongin-si (KR)

Correspondence Address: HARNESS, DICKEY & PIERCE, P.L.C., P.O. BOX 8910, RESTON, VA, 20195, US

(73) Assignee: Samsung Electronics Co., LTD.

(21) Appl. No.: 11/350,856

(22) Filed: Feb. 10, 2006

(30) Foreign Application Priority Data
Jul. 8, 2005 (KR) 10-2005-0061785

(51) Int. Cl. G11C 11/00

(52) U.S. Cl. 365/163

(57) ABSTRACT

A phase change memory device and a method of fabricating the same. The phase change memory device may include a lower electrode which is electrically connected to a transistor formed on a semiconductor substrate, a first insulation layer which covers the lower electrode and the substrate and has a first hole exposing the lower electrode, a conductive contact formed in the first hole, a second insulation layer which is formed on the first insulation layer has a second hole corresponding to the conductive contact, a phase change material layer which fills the second hole, and an upper electrode which covers an upper surface of the phase change material layer.

### PRIORITY STATEMENT

This application claims the benefit of Korean Patent Application No. 10-2005-0061785, filed on Jul. 8, 2005, in the Korean Intellectual Property Office, the disclosure of which is incorporated herein in its entirety by reference.

### BACKGROUND OF THE INVENTION

1. Field of the Invention

Example embodiments of the present invention relate to a phase change memory device and a method of fabricating the same, and more particularly, to a phase change memory device and a method of fabricating the same in which damage to a phase change material therein during etching is reduced or prevented.

2. Description of the Related Art

A phase change memory device may be formed of one or more phase change material. A phase change material enters a crystalline or amorphous state according to the magnitude of a current, e.g., joule energy, supplied to the phase change material, and thus electric conductivity thereof may be changed. Logic information, for example, ‘0’ and ‘1’, may be stored in a memory cell including a phase change material by changing the state of the phase change material by applying a current with a desired magnitude to the phase change material, and the logic information, for example, ‘0’ and ‘1’, stored in a memory cell may be read by detecting the resistance of the memory cell.

FIG. 1 is a cross-sectional view of a conventional phase change memory device. Referring to FIG. 1, a conventional phase change memory device may include a lower electrode 10, an upper electrode 18, a phase change material layer, for example, a thin phase change material layer 16, interposed between the lower and upper electrodes 10 and 18, and/or a conductive contact 14 electrically contacting the lower electrode 10 and the phase change material layer 16.

Side portions of the lower electrode 10 and the conductive contact 14 may contact inner walls of an insulation layer 12, and the lower electrode 10 may electrically contact a switching device (not illustrated), for example, a transistor.

In order to form the phase change material layer 16 and the upper electrode 18 on the conductive contact 14, the phase change material and a conductive layer may be stacked on the insulation layer 12 and etching is performed.

An exposed surface of the phase change material layer 16 may be damaged during etching, thereby degrading the phase change characteristics of the memory device. For example, the damage caused by etching may increase as the width of the phase change material layer 16 decreases in a smaller-sized phase change memory device.

### SUMMARY OF THE INVENTION

Example embodiments of the present invention provide a phase change memory device, in which a phase change material is not exposed when etching an upper electrode, and a method of fabricating the same.

According to an example embodiment of the present invention, there is provided a phase change memory device including a lower electrode formed on a semiconductor substrate, a first insulation layer which covers the lower electrode and the substrate and has a first hole exposing the lower electrode, a conductive contact formed in the first hole, a second insulation layer which is formed on the first insulation layer has a second hole corresponding to the conductive contact; a phase change material layer which fills the second hole, and an upper electrode which covers an upper surface of the phase change material layer.

In an example embodiment, the upper electrode protects at least the upper surface of the phase change material layer.

In an example embodiment, the upper electrode protects the upper surface and side surfaces of the phase change material layer.

In an example embodiment, the phase change material layer and the upper electrode are substantially aligned and a width of the upper electrode is greater than a width of the phase change material layer.

In an example embodiment, the width of the upper electrode may be 4/3 to three times of the width of the phase change material layer.

In an example embodiment, the phase change material may be formed of at least one chalcogenide material selected from the group consisting of tellurium (Te), selenium (Se), and sulfur (S).

According to another example embodiment of the present invention, there is provided a method of fabricating a phase change memory device including forming on a semiconductor substrate a lower electrode electrically connected to a transistor in the semiconductor substrate, forming on the substrate a first insulation layer which covers the lower electrode; forming on the first insulation layer a conductive contact which electrically contacts the lower electrode, forming on the first insulation layer a second insulation layer which has a first hole corresponding to the conductive contact, depositing a phase change material to fill the first hole on the second insulation layer, planarizing the second insulation layer and the phase change material, and forming an upper electrode on the second insulation layer and the phase change material layer such that the upper electrode covers an upper surface of the phase change material layer.

In an example embodiment, forming the second insulation layer may include forming the first hole with a first width and the forming of the upper electrode may include forming the upper electrode with a second width greater than the first width.

In an example embodiment, depositing the phase change material to fill the hole may be performed using physical vapor deposition (PVD).

### BRIEF DESCRIPTION OF THE DRAWINGS

The above and other features and advantages of the present invention will become more apparent by describing in detail example embodiments thereof with reference to the attached drawings in which:

FIG. 1 is a cross-sectional view of a conventional phase change memory device;

FIG. 2 is a cross-sectional view of a phase change memory device according to an example embodiment of the present invention; and

FIGS. 3A through 3G are cross-sectional views illustrating stages in a method of fabricating a phase change memory device according to an example embodiment of the present invention.

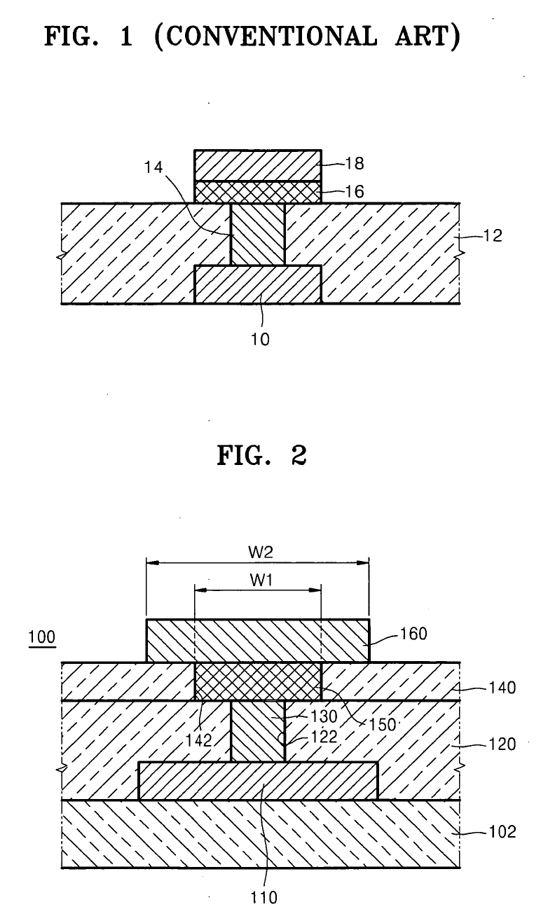

### DETAILED DESCRIPTION OF EXAMPLE EMBODIMENTS OF THE INVENTION

Hereinafter, the present invention will be described more fully with reference to the accompanying drawings, in which example embodiments of the invention are shown. In the drawings, like reference numerals denote like element, and the sizes and thicknesses of layers and regions are exaggerated for clarity.

Various example embodiments of the present invention will now be described more fully with reference to the accompanying drawings in which some example embodiments of the invention are shown. In the drawings, the thicknesses of layers and regions may be exaggerated for clarity.

Detailed illustrative embodiments of the present invention are disclosed herein. However, specific structural and functional details disclosed herein are merely representative for purposes of describing example embodiments of the present invention. This invention may, however, may be embodied in many alternate forms and should not be construed as limited to only the embodiments set forth herein.

Accordingly, while example embodiments of the invention are capable of various modifications and alternative forms, embodiments thereof are shown by way of example in the drawings and will herein be described in detail. It should be understood, however, that there is no intent to limit example embodiments of the invention to the particular forms disclosed, but on the contrary, example embodiments of the invention are to cover all modifications, equivalents, and alternatives falling within the scope of the invention. Like numbers refer to like elements throughout the description of the figures.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of example embodiments of the present invention. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between”, “adjacent” versus “directly adjacent”, etc.).

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises”, “comprising,”, “includes” and/or “including”, when used herein, specify the presence of stated features, integers, steps, operations, elements, and/or components, but do not preclude the presence or addition of one or more other features, integers, steps, operations, elements, components, and/or groups thereof.

It will be understood that when an element or layer is referred to as being “on”, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numbers refer to like elements throughout. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the scope of example embodiments of the present invention.

Spatially relative terms, such as “beneath”, “below”, “lower”, “above”, “upper” and the like, may be used herein for ease of description to describe one element or a feature's relationship to another element or feature as illustrated in the Figures. It will be understood that the spatially relative terms are intended to encompass different orientations of the device in use or operation in addition to the orientation depicted in the Figures. For example, if the device in the Figures is turned over, elements described as “below” or “beneath” other elements or features would then be oriented “above” the other elements or features. Thus, for example, the term “below” can encompass both an orientation which is above as well as below. The device may be otherwise oriented (rotated 90 degrees or viewed or referenced at other orientations) and the spatially relative descriptors used herein should be interpreted accordingly.

The terminology used herein is for the purpose of describing particular embodiments only and is not intended to be limiting of example embodiments of the invention. As used herein, the singular forms “a”, “an” and “the” are intended to include the plural forms as well, unless the context clearly indicates otherwise. It will be further understood that the terms “comprises,” “comprising,” “includes” and/or “including,” when used in this specification, specify the presence of stated features, integers, steps, operations, elements, and/or components, but do not preclude the presence or addition of one or more other features, integers, steps, operations, elements, components, and/or groups thereof.

Also, the use of the words “compound,” “compounds,” or “compound(s),” refer to either a single compound or to a plurality of compounds. These words are used to denote one or more compounds but may also just indicate a single compound.

Example embodiments of the present invention are described herein with reference to cross-sectional illustrations that are schematic illustrations of idealized embodiments (and intermediate structures). As such, variations from the shapes of the illustrations as a result, for example, of manufacturing techniques and/or tolerances, may be expected. Thus, example embodiments of the invention should not be construed as limited to the particular shapes of regions illustrated herein but may include deviations in shapes that result, for example, from manufacturing. For example, an implanted region illustrated as a rectangle may have rounded or curved features and/or a gradient (e.g., of implant concentration) at its edges rather than an abrupt change from an implanted region to a non-implanted region. Likewise, a buried region formed by implantation may result in some implantation in the region between the buried region and the surface through which the implantation may take place. Thus, the regions illustrated in the figures are schematic in nature and their shapes do not necessarily illustrate the actual shape of a region of a device and do not limit the scope of the present invention.

It should also be noted that in some alternative implementations, the functions/acts noted may occur out of the order noted in the FIGS. For example, two FIGS. shown in succession may in fact be executed substantially concurrently or may sometimes be executed in the reverse order, depending upon the functionality/acts involved.

Unless otherwise defined, all terms (including technical and scientific terms) used herein have the same meaning as commonly understood by one of ordinary skill in the art to which example embodiments of the present invention belong. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

In order to more specifically describe example embodiments of the present invention, various aspects of the present invention will be described in detail with reference to the attached drawings. However, the present invention is not limited to the example embodiments described. In the figures, if a layer is formed on another layer or a substrate, it means that the layer is directly formed on another layer or a substrate, or that a third layer is interposed therebetween. In the following description, the same reference numerals denote the same elements.

FIG. 2 is a cross-sectional view of a phase change memory device 100 according to an example embodiment of the present invention. Referring to FIG. 2, the phase change memory device 100 may include a lower electrode 110 electrically connected to a switching device (not illustrated), for example, a source electrode or drain electrode of a transistor. The lower electrode 110 may be formed on a semiconductor substrate 102 and a first insulation layer 120 covering the lower electrode 110 may be formed on the substrate 102. A contact hole 122 exposing the lower electrode 110 may be formed in the first insulation layer 120 and may be filled with a conductive contact 130.

A second insulation layer 140 may be formed on the first insulation layer 120 and may have a hole 142 exposing the conductive contact 130. The hole 142 may have a first width W1. A phase change material layer 150 may fill the hole 142.

The phase change material layer 150 may be formed of at least one chalcogenide material selected from the group consisting of tellurium (Te), selenium (Se), and sulfur (S).

In other example embodiments, the phase change material layer 150 may include other chalcogenide alloys such as germanium-antimony-tellurium (Ge—Sb—Te), arsenic-antimony-tellurium (As—Sb—Te), tin-antimony-tellurium (Sn—Sb—Te), or tin-indium-antimony-tellurium (Sn—In—Sb—Te), arsenic-germanium-antimony-tellurium (As—Ge—Sb—Te). Alternatively, the phase change material layer 150 may include an element in Group VA-antimony-tellurium such as tantalum-antimony-tellurium (Ta—Sb—Te), niobium-antimony-tellurium (Nb—Sb—Te) or vanadium-antimony-tellurium (V—Sb—Te) or an element in Group VA-antimony-selenium such as tantalum-antimony-selenium (Ta—Sb—Se), niobium-antimony-selenium (Nb—Sb—Se) or vanadium-antimony-selenium (V—Sb—Se). Further, the phase change material layer 150 may include an element in Group VIA-antimony-tellurium such as tungsten-antimony-tellurium (W—Sb—Te), molybdenum-antimony-tellurium (Mo—Sb—Te), or chrome-antimony-tellurium (Cr—Sb—Te) or an element in Group VIA-antimony-selenium such as tungsten-antimony-selenium (W—Sb—Se), molybdenum-antimony-selenium (Mo—Sb—Se) or chrome-antimony-selenium (Cr—Sb—Se).

Although the phase change material layer 150 is described above as being formed primarily of ternary phase-change chalcogenide alloys, the chalcogenide alloy could be selected from a binary phase-change chalcogenide alloy or a quaternary phase-change chalcogenide alloy. Example binary phase-change chalcogenide alloys may include one or more of Ga—Sb, In—Sb, In—Se, Sb₂—Te₃ or Ge—Te alloys; example quaternary phase-change chalcogenide alloys may include one or more of an Ag—In—Sb—Te, (Ge—Sn)—Sb—Te, Ge—Sb—(Se—Te) or Te₈₁—Ge₁₅—Sb₂—S₂ alloy, for example.

In an example embodiment, the phase change material layer 150 may be made of a transition metal oxide having multiple resistance states, as described above. For example, the phase change material layer 150 may be made of at least one material selected from the group consisting of NiO, TiO₂, HfO, Nb₂O₅, ZnO, WO₃, and CoO or GST (Ge₂Sb₂Te₅) or PCMO(PrₓCa₁₋ₓMnO₃). The phase change material layer 150 may be a chemical compound including one or more elements selected from the group consisting of S, Se, Te, As, Sb, Ge, Sn, In and Ag.

An upper electrode 160 contacting the phase change material layer 150 may be formed on the second insulation layer 140. The upper electrode 160 may be centrally aligned with respect to the phase change material layer 150. A second width W2 of the upper electrode 160 may be greater than the first width W1 and may be 4/3 to three times of the first width W1. The positions and sizes of upper electrode 160 and the phase change material layer 150 may be such that the surface of the phase change material layer 150 is not exposed when etching the upper electrode 160.

In an example embodiment, the conductive contact 130 may be formed of TiN or TiAlN.

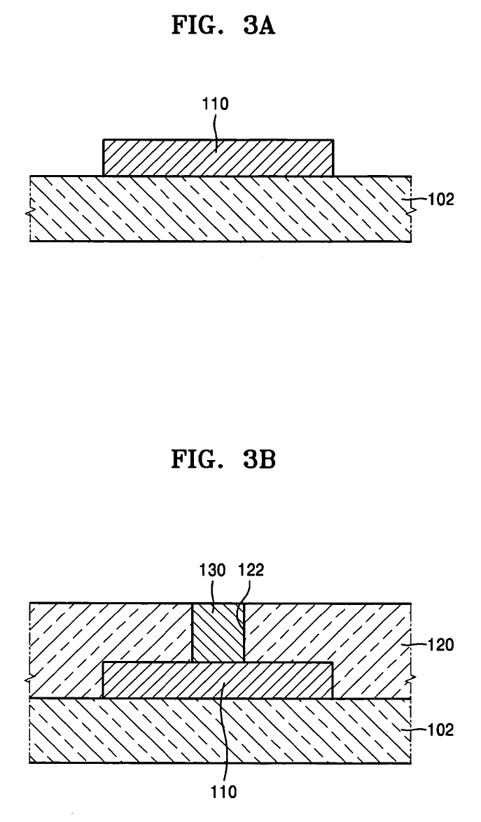

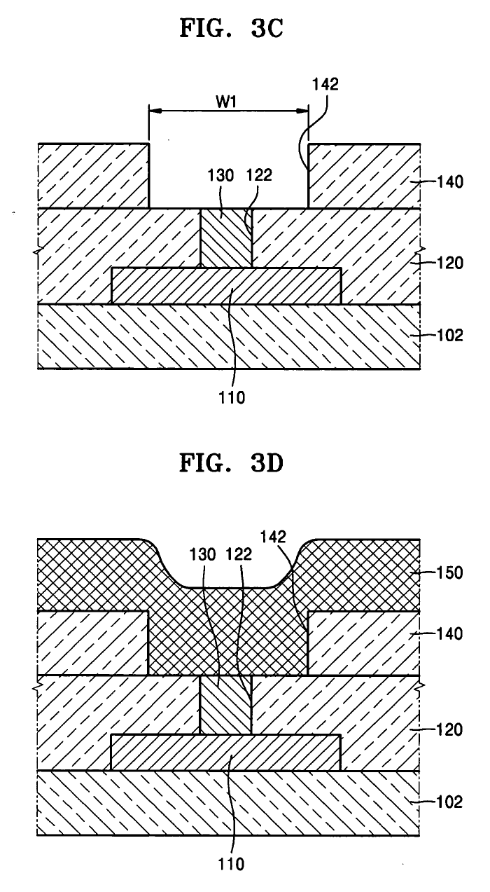

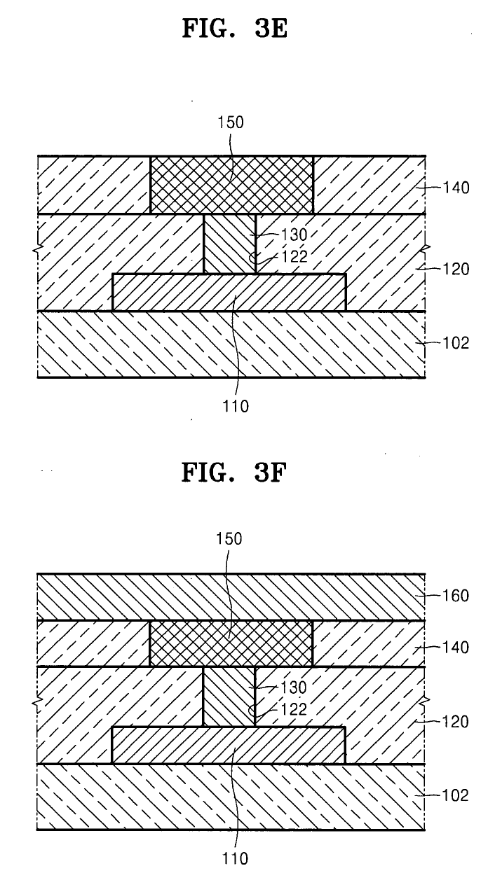

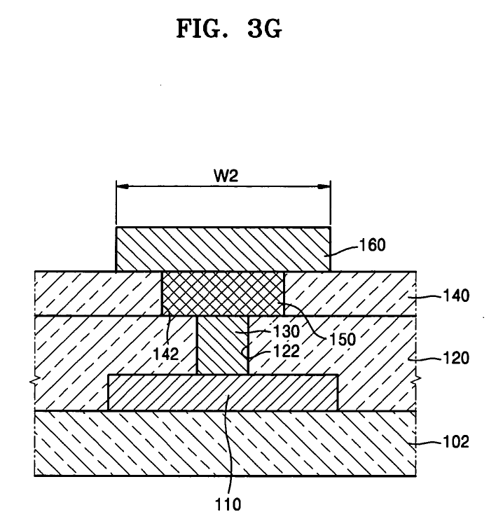

FIGS. 3A through 3G are cross-sectional views illustrating stages in a method of fabricating a phase change memory device according to an example embodiment of the present invention.

Referring to FIG. 3A, a transistor (not illustrated) is formed on a semiconductor substrate 102 using a conventional method and an electrode layer is formed on the substrate 102. Then, a lower electrode 110 is formed by patterning the electrode layer using a conventional patterning process. The lower electrode 110 is patterned to be electrically connected to a source region of the transistor.

Referring to FIG. 3B, a first insulation layer 120 covering the lower electrode 110 may be deposited on the substrate 102. The first insulation layer 120 may be patterned to form a contact hole 122 exposing the lower electrode 110. A conductive contact 130 may be formed by filling the contact hole 122 with a conductive material, for example, TiN, or TiAlN.

Referring to FIG. 3C, a second insulation layer 140 may be formed on the first insulation layer 120. The second insulation layer 140 may be etched to form a hole 142 having a first width W1 greater than the upper width of the conductive contact 130, thereby exposing the conductive contact 130.

Referring to FIG. 3D, the hole 142 may be filled with a phase change material layer 150, for example, using physical vapor deposition (PVD).

In an example embodiment, the phase change material layer 150 may be formed of at least one chalcogenide material selected from the group consisting of tellurium (Te), selenium (Se), and sulfur (S) or any of the chalcogenide materials mentioned above.

Referring to FIG. 3E, upper surfaces of the phase change material layer 150 and the second insulation layer 140 may be planarized, for example, by chemical mechanical polishing (CMP).

Referring to FIG. 3F, a conductive layer 160 may be formed on the phase change material layer 150.

Referring to FIG. 3G, an upper electrode 160 having a second width W2 may be formed on the phase change material layer 150 by patterning the conductive layer 162. The upper electrode 160 may be centrally aligned with respect to the phase change material layer 150. The second width W2 of the upper electrode 160 may be greater than the first width W1, and may be 4/3 to three times of the first width W1. In an example embodiment, the positions and sizes of upper electrode 160 and the phase change material layer 150 may be such that the surface of the phase change material layer 150 is not exposed when etching the upper electrode 160.

According to example embodiments of the phase change memory device and method of fabricating the same of the present invention, because a phase change material layer formed on an insulation layer is not exposed when etching an upper electrode, the phase change material layer is not damaged during etching. Thus, a phase change memory cell having improved phase change properties may be manufactured.

While the present invention has been particularly shown and described with reference to example embodiments thereof, it will be understood by those of ordinary skill in the art that various changes in form and details may be made therein without departing from the spirit and scope of the present invention as defined by the following claims.

What is claimed is:

1. A phase change memory device comprising:
a lower electrode;
a first insulation layer which covers the lower electrode and the substrate and has a first hole exposing the lower electrode;
a conductive contact formed in the first hole;
a second insulation layer on the first insulation layer having a second hole corresponding to the conductive contact;
a phase change material layer which fills the second hole; and
an upper electrode which covers an upper surface of the phase change material layer.

2. The device of claim 1, wherein the upper electrode protects at least the upper surface of the phase change material layer.

3. The device of claim 2, wherein the upper electrode protects the upper surface and side surfaces of the phase change material layer.

4. The device of claim 1, wherein the phase change material layer and the upper electrode are substantially aligned and a width of the upper electrode is greater than a width of the phase change material layer.

5. The device of claim 4, wherein the width of the upper electrode is 4/3 to three times of the width of the phase change material layer.

6. The device of claim 1, wherein the phase change material is formed of at least one chalcogenide material selected from the group consisting of tellurium (Te), selenium (Se), and sulfur (S).

7. A method of fabricating a phase change memory device comprising:
forming on a semiconductor substrate a lower electrode;
forming on the substrate a first insulation layer which covers the lower electrode;
forming on the first insulation layer a conductive contact which electrically contacts the lower electrode;
forming on the first insulation layer a second insulation layer which has a first hole corresponding to the conductive contact;
depositing a phase change material to fill the first hole on the second insulation layer;
planarizing the second insulation layer and the phase change material; and
forming an upper electrode on the second insulation layer and the phase change material layer such that the upper electrode covers an upper surface of the phase change material layer.

8. The method of claim 7, wherein the upper electrode is formed to protect at least the upper surface of the phase change material layer.

9. The method of claim 7, wherein the upper electrode is formed to protect the upper surface and side surfaces of the phase change material layer.

10. The method of claim 7, wherein the phase change material layer and the upper electrode are substantially aligned and a width of the upper electrode is greater than a width of the phase change material layer.

11. The method of claim 7, wherein forming the second insulation layer includes forming the first hole with a first width and forming the upper electrode includes forming the upper electrode with a second width greater than the first width.

12. The method of claim 11, wherein the phase change material layer and the upper electrode are substantially aligned.

13. The method of claim 12, wherein the second width is 4/3 to three times of the first width.

14. The method of claim 7, wherein depositing the phase change material to fill the hole is performed using physical vapor deposition (PVD).

15. The method of claim 7, wherein the phase change material is formed of at least one chalcogenide material selected from the group consisting of tellurium (Te), selenium (Se), and sulfur (S).

16. A phase change memory device including the lower electrode, the first insulation layer covering the lower electrode and the substrate and having a first hole exposing the lower electrode, the conductive contact formed in the first hole, the second insulation layer on the first insulation layer having a second hole corresponding to the conductive contact, the phase change material layer filling the second hole, and the upper electrode covering an upper surface of the phase change material layer, the phase change memory device being fabricated in accordance with the method of claim 7.
